(19) United States
(12) Patent Application Publication
(10) Pub. No.: US 2026/0231533 A1
(43) Pub. Date: Aug. 6, 2026

(54) SEMICONDUCTOR DEVICE

(71) Applicant: United Semiconductor Japan Co., Ltd., Kuwana-shi (JP)

(72) Inventors: Katsuyoshi Matsuura, Kuwana-shi (JP); Kazuhiro Mizutani, Kuwana-shi (JP)

(73) Assignee: United Semiconductor Japan Co., Ltd., Kuwana-shi (JP)

(21) Appl. No.: 19/045,537

(22) Filed: Feb. 4, 2025

(51) Int. Cl. H10D 89/60

(52) U.S. Cl. CPC H10D 89/611

(57) ABSTRACT

A semiconductor device includes a semiconductor substrate including a first portion, a second portion, and a third portion, a first p-type well region at least partly disposed in the first portion, a first n-type well region disposed in the second portion, a second p-type well region, a second n-type well region disposed in the third portion, and a deep n-type well region. A part of the first n-type well region is located between the first p-type well region and the second p-type well region. A part of the second p-type well region is located between the first n-type well region and the second n-type well region. The deep n-type well region is partly located under the first p-type well region, partly located under the first n-type well region, and partly located under the second p-type well region. The deep n-type well region is separated from the second n-type well region.

### BACKGROUND OF THE INVENTION

### 1. Field of the Invention

The present invention relates to a semiconductor device, and more particularly, to a semiconductor device including a deep well region.

### 2. Description of the Prior Art

Electrostatic discharge (ESD) is a discharge effect where charges accumulate on a non-conductor or an ungrounded conductor and travel rapidly through a discharge path in a short period of time, and ESD can cause damage to integrated circuits. Generally, the human bodies, the machines for IC packaging, the instruments for testing the integrated circuit, etc. are all common charged bodies. When the charged body is in contact with the chip or wafer, the charged body will discharge to the chip or wafer. The transient power of electrostatic discharge can cause damage or failure of the wafer or integrated circuits within the wafer. Therefore, ESD protection structures are provided in integrated circuits for improving the above-mentioned problems.

### SUMMARY OF THE INVENTION

A semiconductor device is provided in the present invention. A deep n-type well region is partly located under a first p-type well region within a diode region, partly located under a first n-type well region within a guard ring region, and partly located under a second p-type well region for improving a latch-up issue in an internal circuit region.

According to an embodiment of the present invention, a semiconductor device is provided. The semiconductor device includes a semiconductor substrate, a first p-type well region, a first n-type well region, a second p-type well region, a second n-type well region, and a deep n-type well region. The semiconductor substrate includes a first portion located within a diode region, a second portion located within a guard ring region, and a third portion located within an internal circuit region. At least a part of the first p-type well region is disposed in the first portion. The first n-type well region is disposed in the second portion. A part of the first n-type well region is located between the first p-type well region and the second p-type well region in a horizontal direction. The second n-type well region is disposed in the third portion. A part of the second p-type well region is located between the first n-type well region and the second n-type well region in the horizontal direction. The deep n-type well region is disposed in the semiconductor substrate. The deep n-type well region is partly located under the first p-type well region, partly located under the first n-type well region, and partly located under the second p-type well region, and the deep n-type well region is separated from the second n-type well region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to a first embodiment of the present invention.

FIG. 2 is a top view schematic drawing illustrating a semiconductor device according to an embodiment of the present invention.

FIG. 3 is a schematic drawing illustrating an operation condition of a semiconductor device according to an embodiment of the present invention.

FIG. 4 is a schematic drawing illustrating a relationship between a length of a part of a deep n-type well region and trigger current according to an embodiment of the present invention.

FIG. 5 is a schematic drawing illustrating a semiconductor device according to a second embodiment of the present invention.

FIG. 6 is a schematic drawing illustrating a semiconductor device according to a third embodiment of the present invention.

FIG. 7 is a schematic drawing illustrating a semiconductor device according to a fourth embodiment of the present invention.

FIG. 8 is a schematic drawing illustrating a semiconductor device according to a fifth embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

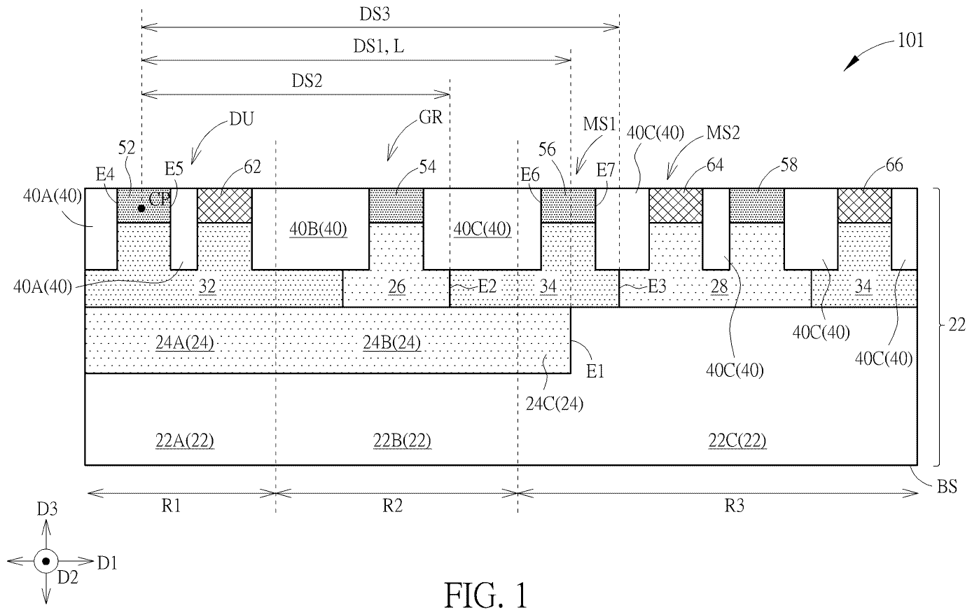

Please refer to FIG. 1. FIG. 1 is a schematic drawing illustrating a semiconductor device 101 according to a first embodiment of the present invention. As shown in FIG. 1, the semiconductor device 101 includes a semiconductor substrate 22, a first p-type well region 32, a first n-type well region 26, a second p-type well region 34, a second n-type well region 28, and a deep n-type well region 24. The semiconductor substrate 22 includes a first portion 22A, a second portion 22B, and a third portion 22C. The first portion 22A is located within a diode region R1, the second portion 22B is located within a guard ring region R2, and a third portion 22C is located within an internal circuit region R3. At least a part of the first p-type well region 32 is disposed in the first portion 22A. The first n-type well region 26 is disposed in the second portion 22B. A part of the first n-type well region 26 is located between the first p-type well region 32 and the second p-type well region 34 in a horizontal direction (such as a horizontal direction D1). The second n-type well region 28 is disposed in the third portion 22C, and a part of the second p-type well region 34 is located between the first n-type well region 26 and the second n-type well region 28 in the horizontal direction D1. The deep n-type well region 24 is disposed in the semiconductor substrate 22. The deep n-type well region 24 is partly located under the first p-type well region 32 in a vertical direction D3, partly located under the first n-type well region 26 in the vertical direction D3, and partly located under the second p-type well region 34 in the vertical direction D3, and the deep n-type well region 24 is separated from the second n-type well region 28. The deep n-type well region 24 is extended to be partly located under the second p-type well region 34 for reducing electrons passing through the first p-type well region 32, the deep n-type well region 24, and the semiconductor substrate 22 and flowing into the second n-type well region 28. Related issues (such as a latch-up issue) may be improved accordingly.

Specifically, in some embodiments, the semiconductor substrate 22 may include a silicon substrate, an epitaxial silicon substrate, a silicon germanium substrate, a silicon carbide substrate, a silicon-on-insulator (SOI) substrate, or a substrate made of other suitable semiconductor materials. The vertical direction D3 may be regarded as a thickness direction of the semiconductor substrate 22. The semiconductor substrate 22 may have a top surface and a bottom surface BS opposite to the top surface in the vertical direction D3, and the first p-type well region 32, the first n-type well region 26, the second p-type well region 34, and the second n-type well region 28 described above may be located adjacent to the top surface. A horizontal direction substantially orthogonal to the vertical direction D3 (such as the horizontal direction D1 and a horizontal direction D2) may be substantially parallel with the top surface and/or the bottom surface BS of the semiconductor substrate 22, but not limited thereto. Additionally, in this description, a distance between the bottom surface BS of the semiconductor substrate 22 and a relatively higher location and/or a relatively higher part in the vertical direction D3 may be greater than a distance between the bottom surface BS of the semiconductor substrate 22 and a relatively lower location and/or a relatively lower part in the vertical direction D3. The bottom or a lower portion of each component may be closer to the bottom surface BS of the semiconductor substrate 22 in the vertical direction D3 than the top or upper portion of this component, but not limited thereto. In this description, the condition that a certain component is disposed between two other components in a specific direction may include but is not limited to a condition that the certain component is sandwiched between the two other components in the specific direction. In this description, the condition that a certain component surrounds another one component in horizontal directions may include a condition that the certain component is partly located at two opposite sides of the another one component in one horizontal direction and partly located at two opposite sides of the another one component in another horizontal direction.

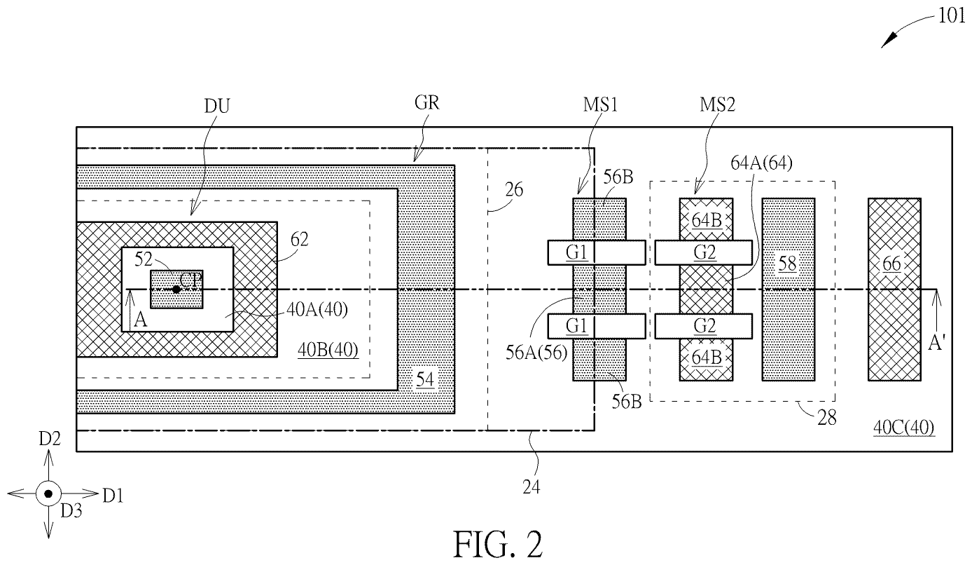

Please refer to FIG. 1 and FIG. 2. FIG. 2 is a top view schematic drawing illustrating a semiconductor device according to an embodiment of the present invention. In some embodiments, FIG. 1 may be regarded as a cross-sectional diagram taken along a line A-A′ in FIG. 2, but not limited thereto. As shown in FIG. 1 and FIG. 2, in some embodiments, the semiconductor device 101 may further include an isolation structure 40, a first n-type doped region 52, a second n-type doped region 54, a third n-type doped region 56, a fourth n-type doped region 58, a first p-type doped region 62, a second p-type doped region 64, and a third p-type doped region 66. The isolation structure 40 may be disposed in the semiconductor substrate 22 and the isolation structure 40 may include a single layer or multiple layers of insulation materials, such as oxide insulation materials (silicon oxide, for example) or other suitable insulation materials. In some embodiments, the well regions (such as the first p-type well region 32, the second p-type well region 34, the first n-type well region 26, the second n-type well region 28, and the deep n-type well region 24) and the doped regions (such as the first n-type doped region 52, the second n-type doped region 54, the third n-type doped region 56, the fourth n-type doped region 58, the first p-type doped region 62, the second p-type doped region 64, and the third p-type doped region 66) may be doped regions formed by doping processes (such as implantation processes) in the semiconductor substrate 22. In other words, the well regions and the doped regions may include a part of the semiconductor substrate 22 (i.e. having the same material with the semiconductor substrate 22) respectively and dopants formed in the semiconductor substrate 22. In some embodiments, dopants for forming n-type doped regions may include phosphorous (P), arsenic (As), or other suitable materials, and dopants for forming p-type doped regions may include boron (B), boron difluoride (BF₂), or other suitable materials.

The first n-type doped region 52 and the first p-type doped region 62 may be disposed in the first p-type well region 32 and located within the diode region R1. A part of the isolation structure 40 (such as a first portion 40A of the isolation structure 40) may be disposed between the first n-type doped region 52 and the first p-type doped region 62 in the horizontal direction. In some embodiments, in the top-view of the semiconductor device 101 or viewed in the vertical direction D3, the first p-type doped region 62 may surround the first n-type doped region 52 and the first portion 40A of the isolation structure 40 in the horizontal directions (such as the horizontal direction D1 and the horizontal direction D2 orthogonal to the horizontal direction D1), and the first portion 40A of the isolation structure 40 may surround the first n-type doped region 52 in the horizontal directions. The first n-type doped region 52 and the first p-type doped region 62 may be a part of a diode structure, such as a diode structure DU including the first n-type doped region 52, the first p-type doped region 62, and a part of the first p-type well region 32. In some embodiments, the diode structure DU may be an electrostatic discharge (ESD) protection diode structure, but not limited thereto.

The second n-type doped region 54 may be disposed in the first n-type well region 26 and located within the guard ring region R2. A part of the isolation structure 40 (such as a second portion 40B of the isolation structure 40) may be disposed between the second n-type doped region 54 and the first p-type doped region 62 in the horizontal direction. At least a part of the first p-type doped region 62 may be located between the first n-type doped region 52 and the second n-type doped region 54 in the horizontal direction D1. In some embodiments, the second n-type doped region 54 may surround the first p-type doped region 62 and the second portion 40B of the isolation structure 40 in the horizontal directions (such as the horizontal direction D1 and the horizontal direction D2), the second portion 40B of the isolation structure 40 may surround the first p-type doped region 62 in the horizontal directions, and the first n-type well region 26 may surround the first p-type well region 32 in the horizontal directions, but not limited thereto. In some embodiments, the second n-type doped region 54 and the first n-type well region 26 are at least a part of a guard ring structure GR, and the guard ring structure GR may surround the diode structure DU in the horizontal directions.

In some embodiments, the second p-type well region 34 may be partly located within the internal circuit region R3 and partly located within the guard ring region R2, and the second p-type well region 34 may surround the second n-type well region 28 in the horizontal directions, but not limited thereto. In some embodiments, the second p-type well region 34 may not be located within the internal circuit region R3. The third n-type doped region 56 and the third p-type doped region 66 are disposed in the second p-type well region 34. The second p-type doped region 64 and the fourth n-type doped region 58 are disposed in the second n-type well region 28 and located within the internal circuit region R3. A part of the isolation structure 40 (such as a third portion 40C of the isolation structure 40) may surround the third n-type doped region 56, the second p-type doped region 64, the fourth n-type doped region 58, and the third p-type doped region 66 in the horizontal directions. A part of the second n-type doped region 54 may be located between the first p-type doped region 62 and the third n-type doped region 56 in the horizontal direction D1. The third n-type doped region 56 may be located between the second n-type doped region 54 and the second p-type doped region 64 in the horizontal direction D1. The second p-type doped region 64 may be located between the third n-type doped region 56 and the fourth n-type doped region 58 in the horizontal direction D1, and the fourth n-type doped region 58 may be located between the second p-type doped region 64 and the third p-type doped region 66 in the horizontal direction D1.

In some embodiments, the third n-type doped region 56 may be a source/drain region (such as a source/drain region 56A) of an n-type transistor structure MS1, the second p-type doped region 64 may be a source/drain region (such as a source/drain region 64A) of a p-type transistor structure MS2, and the semiconductor device 101 may further include a gate structure G1, a gate structure G2, a source/drain region 56B, and a source/drain region 64B, but not limited thereto. The n-type transistor structure MS1 may include the gate structure G1, the third n-type doped region 56, and the source/drain region 56B, and the p-type transistor structure MS2 may include the gate structure G2, the second p-type doped region 64, and the source/drain region 64B. The source/drain region 56B may be another n-type doped region, and the source/drain region 56B and the third n-type doped region 56 may be disposed at two opposite sides of the gate structure G1 in the horizontal direction D2 and separated from each other. The source/drain region 64B may be another p-type doped region, and the source/drain region 64B and the second n-type doped region 64 may be disposed at two opposite sides of the gate structure G2 in the horizontal direction D2 and separated from each other. In some embodiments, the n-type transistor structure MS1 and/or the p-type transistor structure MS2 may be a dummy transistor structure in the internal circuit region R3, and the fourth n-type doped region 58 and/or the third p-type doped region 66 may be a dummy doped region in the internal circuit region R3, but not limited thereto. The gate structure G1 and the gate structure G2 may respectively include a gate dielectric layer (not shown) and a gate material layer (not shown) disposed on the gate dielectric layer. The gate dielectric layer may include high dielectric constant (high-k) materials or other suitable dielectric materials (such as silicon oxide). The gate material layer may include non-metallic electrically conductive materials (such as doped polysilicon) or metal electrically conductive materials, such as a metal gate structure formed with a work function layer and a low electrical resistivity layer stacked with each other, but not limited thereto.

The deep n-type well region 24 may include a first portion 24A, a second portion 24B, and a third portion 24C located within the diode region R1, the guard ring region R2, and the internal circuit region R3, respectively. The first portion 24A, the second portion 24B, and the third portion 24C of the deep n-type well region 24 may be directly connected with one another. In some embodiments, the deep n-type well region 24 may be partly located under and directly connected with the first p-type well region 32, partly located under and directly connected with the first n-type well region 26, and partly located under and directly connected with the second p-type well region 34, but not limited thereto. The deep n-type well region 24 is located between the first p-type well region 32 and the semiconductor substrate 22 in the vertical direction D3 for separating the diode structure DU from the semiconductor substrate 22. The deep n-type well region 24 may be partly located under the first n-type doped region 52 in the vertical direction D3, partly located under the first p-type doped region 62 in the vertical direction D3, and partly located under the second n-type doped region 54 in the vertical direction D3. In some embodiments, the deep n-type well region 24 may be partly located under the third n-type doped region 56 in the vertical direction D3, but not limited thereto. The deep n-type well region 24 may include a first edge (such as an edge E1) located under the second p-type well region 34, the first n-typed well region 26 may include a second edge (such as an edge E2) located adjacent to the second p-type well region 34, and the second n-type well region 28 may include a third edge (such as an edge E3) located adjacent to the second p-type well region 34 located between the first n-type well region 26 and the second n-type well region 28 in the horizontal direction D1.

In some embodiments, the edge E1 may be located under the third n-type doped region 56 in the vertical direction D3, a distance DS1 between the edge E1 and a center point CP of the first n-type doped region 52 in the horizontal direction D1 may be greater than a distance DS2 between the edge E2 and the center point CP of the first n-type doped region 52 in the horizontal direction D1, and the distance DS1 may be less than a distance DS3 between the edge E3 and the center point CP of the first n-type doped region 52 in the horizontal direction D1. In some embodiments, the first n-type doped region 52 may include an edge E4 and an edge E5 opposite to the edge E4 in the horizontal direction D1, and the third n-type doped region 56 may include an edge E6 and an edge E7 opposite to the edge E6 in the horizontal direction D1. The edge E5 may be directly connected with the isolation structure 40 located between the first n-type doped region 52 and the first p-type doped region 62 in the horizontal direction D1, and a distance between the center point CP and the edge E4 in the horizontal direction D1 may be substantially equal to a distance between the center point CP and the edge E5 in the horizontal direction D1. The edge E7 may be directly connected with the isolation structure 40 located between the third n-type doped region 56 and the second p-type doped region 64 in the horizontal direction D1, and the distance DS1 may be greater than a distance between the edge E6 and the center point CP in the horizontal direction D1 and less than a distance between the edge E7 and the center point CP in the horizontal direction D1, but not limited thereto. In some embodiments, the distance DS1 may be regarded as a length L of a portion of the deep n-type well region 24 in the horizontal direction D1, such as the deep n-type well region 24 located between the edge E1 and the part of the deep n-type well region 24 located directly under the center point CP in the vertical direction D3. In other words, a length of the deep n-type well region 24 in the horizontal direction D1 is greater than the distance DS1 and the length L defined above.

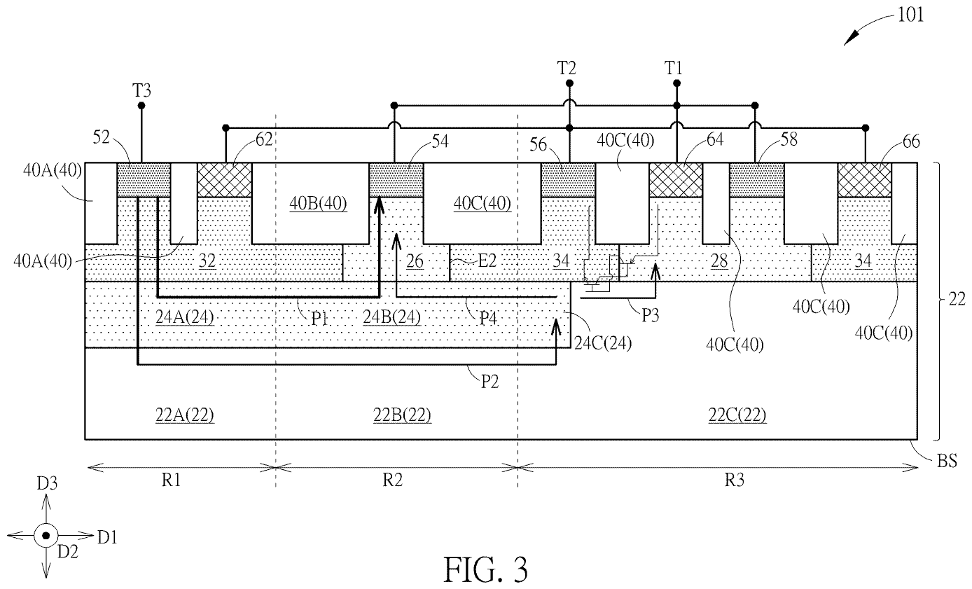

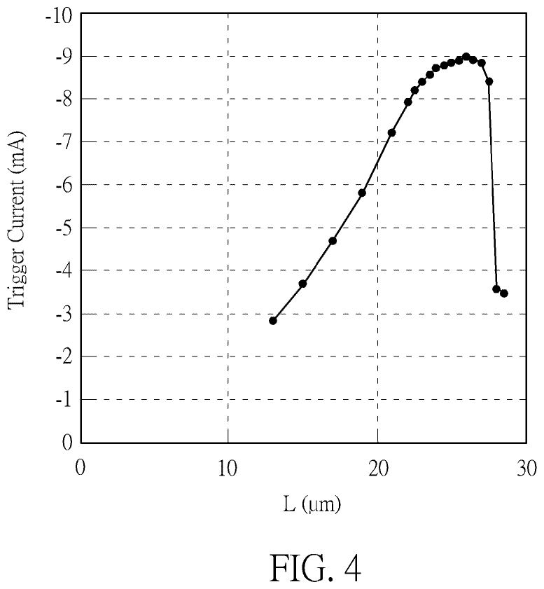

Please refer to FIGS. 1, 3, and 4. FIG. 3 is a schematic drawing illustrating an operation condition of a semiconductor device according to an embodiment of the present invention, and FIG. 4 is a schematic drawing illustrating a relationship between a length of a part of a deep n-type well region and trigger current according to an embodiment of the present invention. As shown in FIG. 1 and FIG. 3, in some embodiments, the second n-type doped region 54, the second p-type doped region 64, and the fourth n-type doped region 58 may be electrically connected to a first voltage terminal (such as terminal T1), the first p-type doped region 62, the third n-type doped region 56, and third p-type doped region 66 may be electrically connected to a second voltage terminal (such as a terminal T2) different from the terminal T1, and the first n-type doped region 52 may be electrically connected to a terminal T3. In some embodiments, the terminal T1 may be a supply voltage terminal and the terminal T2 may be a ground voltage terminal, but not limited thereto. A parasitic PNPN thyristor including the second p-type doped region 64, the second n-type well region 28, the second p-type well region 34, and the third n-type doped region 56 may exist in the semiconductor substrate 22, the parasitic PNPN thyristor may become conductive between the terminal T1 and the terminal T2 when electrons flow into the second n-type well region 28, and latch-up may occur in the internal circuit region R3 where current continues to flow between the terminal T1 and the terminal T2. For example, when a negative current is applied to the first n-type doped region 52 from the terminal T3, electrons may mainly flow to the second n-type doped region 54 along a path P1 illustrated in FIG. 3, and some electrons may flow into the second n-type well region 28 by passing through the first p-type well region 32, the deep n-type well region 24, and the semiconductor substrate 22. By the deep n-type well region 24 expanded to be located under the second p-type well region 34 and/or under the third n-type doped region 56, the electrons flowing along a path P2 illustrated in FIG. 3 may be divided into electrons flowing into the second n-type doped region 54 along a path P3 illustrated in FIG. 3 and electrons flowing into the second n-type well region 28 along a path P4 illustrated in FIG. 3. In other words, the electrons flowing into the second n-type well region 28 may be reduced, and the latch-up issue may be suppressed accordingly.

As shown in FIG. 1, FIG. 3, and FIG. 4, in some embodiments, the distance DS2

described above may be substantially equal to 13 micrometers (μm) and the distance DS3 described above may be substantially equal to 28 μm, and when the length L of the portion of the deep n-type well region 24 in the horizontal direction D1 (i.e. the distance DS1) is substantially equal to 25.75 μm (such as the length L illustrated in FIG. 1), the trigger current applied to the first n-type doped region 52 and turning on the parasitic PNPN thyristor may be about −9 mA. Relatively, when the length L is substantially equal to the distance DS2, the trigger current will be about −2.8 mA, and when the length L is greater than the distance DS3 (the deep n-type well region 24 will be connected with the second n-type well region 28 in this situation), the trigger current will be reduced to be about −3.5 mA. In other words, the deep n-type well region 24 expanded to be located under the second p-type well region 34 and/or under the third n-type doped region 56 without being connected with the second n-type well region 28 may be used to increase the trigger current and suppress the latch-up in the parasitic PNPN thyristor.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

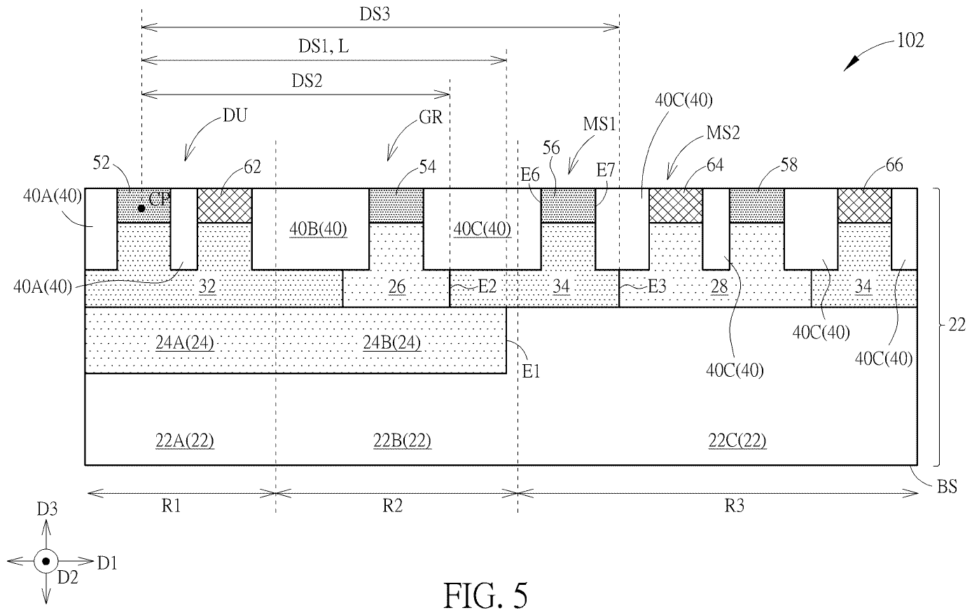

Please refer to FIG. 5. FIG. 5 is a schematic drawing illustrating a semiconductor device 102 according to a second embodiment of the present invention. As shown in FIG. 5, a part of the isolation structure 40 may be located between the second n-type doped region 54 and the third n-type doped region 56 in the horizontal direction D1, and the edge E1 of the deep n-type well region 24 may be located under the part of the isolation structure 40 and the second p-type well region 34 in the vertical direction. In other words, the distance DS1 between the edge E1 and the center point CP of the first n-type doped region 52 in the horizontal direction D1 may be greater than the distance DS2 between the edge E2 and the center point CP in the horizontal direction D1 and less than the distance between the edge E6 and the center point CP in the horizontal direction D1. As shown in FIG. 5 and FIG. 4, in some embodiments, the length L illustrated in FIG. 5 (i.e. the distance DS1) may be about 22 μm, and the trigger current applied to the first n-type doped region 52 and turning on the parasitic PNPN thyristor may be about −7.9 mA. In other words, the deep n-type well region 24 expanded to be located under the second p-type well region 34 without being located directly under the third n-type doped region 56 may still be used to increase the trigger current and suppress the latch-up in the parasitic PNPN thyristor.

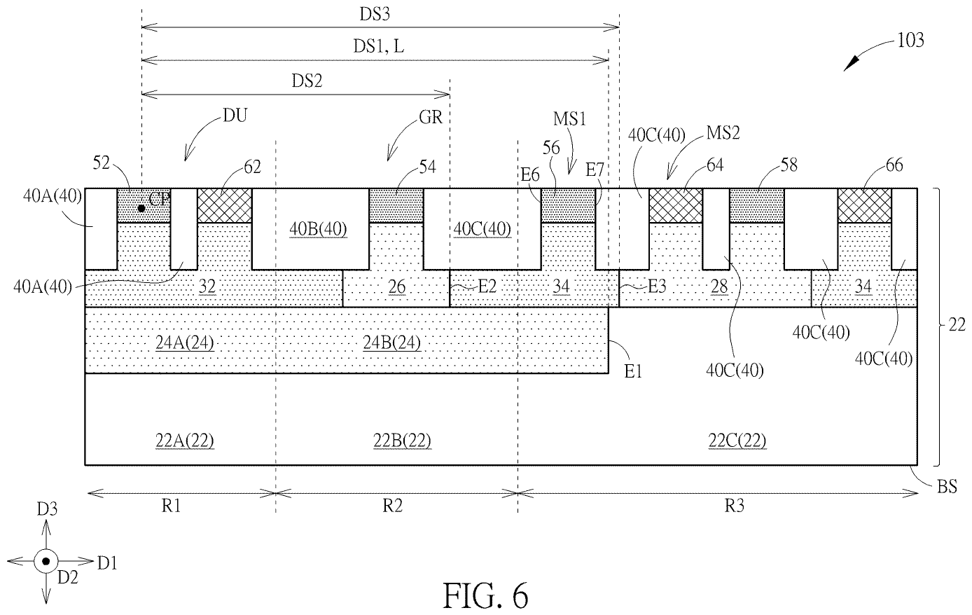

Please refer to FIG. 6. FIG. 6 is a schematic drawing illustrating a semiconductor device 103 according to a third embodiment of the present invention. As shown in FIG. 6, a part of the isolation structure 40 may be located between the third n-type doped region 56 and the second p-type doped region 64 in the horizontal direction D1, and the edge E1 of the deep n-type well region 24 may be located under the part of the isolation structure 40 and the second p-type well region 34 in the vertical direction D3. In other words, the distance DS1 between the edge E1 and the center point CP of the first n-type doped region 52 in the horizontal direction D1 may be greater than the distance between the edge E7 and the center point CP in the horizontal direction D1 and less than the distance DS3 between the edge E3 and the center point CP in the horizontal direction D1. As shown in FIG. 6 and FIG. 4, in some embodiments, the length L illustrated in FIG. 6 (i.e. the distance DS1) may be about 27.7 μm, and the trigger current applied to the first n-type doped region 52 and turning on the parasitic PNPN thyristor may be about −8.4 mA. In other words, the deep n-type well region 24 expanded to be located under the part of the isolation structure 40 located between the third n-type doped region 56 and the second p-type doped region 64 in the horizontal direction D1 without being connected with the second n-type well region 28 may be used to increase the trigger current and suppress the latch-up in the parasitic PNPN thyristor.

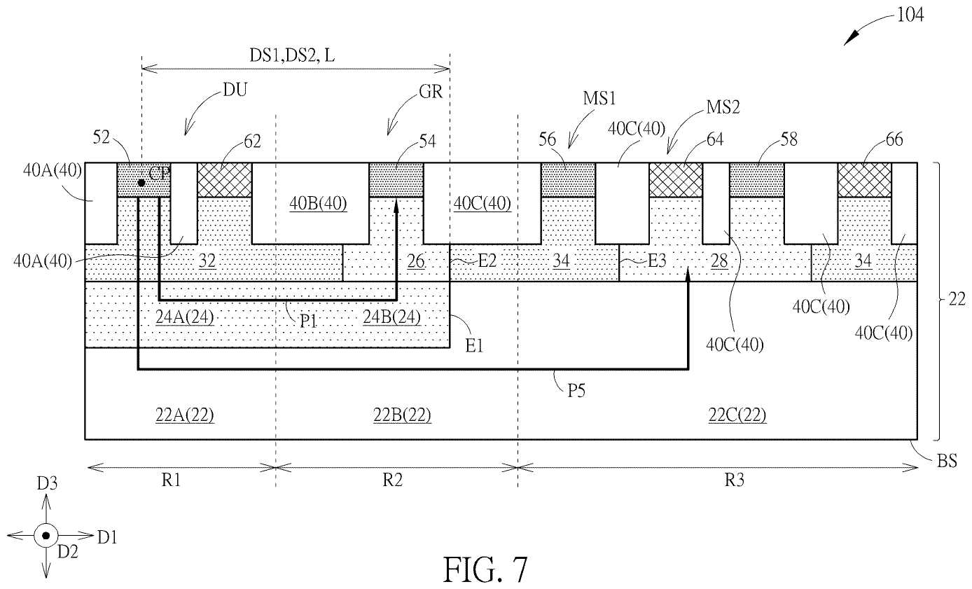

Please refer to FIG. 7. FIG. 7 is a schematic drawing illustrating a semiconductor device 104 according to a fourth embodiment of the present invention. As shown in FIG. 7, when the distance DS1 between the edge E1 and the center point CP in the horizontal direction D1 is substantially equal to the distance DS2 between the edge E2 and the center point CP in the horizontal direction D1, the deep n-type well region 24 is not disposed under the second p-type well region 34 in the vertical direction D3. In this situation, some electrons may flow into the second n-type well region 28 along a path P5 illustrated in FIG. 7, the trigger current applied to the first n-type doped region 52 and turning on the parasitic PNPN thyristor will be decreased, and latch-up may occur in the internal circuit region R3 more easily. As shown in FIG. 7 and FIG. 4, in some embodiments, the length L illustrated in FIG. 7 (i.e. the distance DS1) may be about 13 μm, the trigger current applied to the first n-type doped region 52 and turning on the parasitic PNPN thyristor may be about −2.9 mA, and that is too low to prevent the latch-up in the internal circuit region R3.

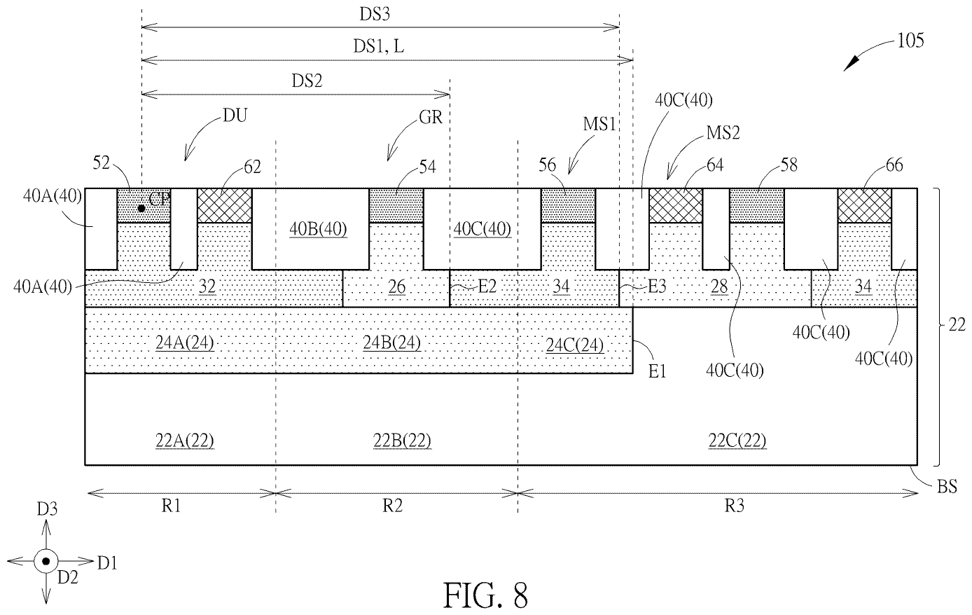

Please refer to FIG. 8. FIG. 8 is a schematic drawing illustrating a semiconductor device 105 according to a fifth embodiment of the present invention. As shown in FIG. 8, when the distance DS1 between the edge E1 and the center point CP in the horizontal direction D1 is greater than the distance DS3 between the edge E3 and the center point CP in the horizontal direction D1, the deep n-type well region 24 is directly connected with the second n-type well region 28, and that will induce more electrons flowing into the second n-type well region 28. The trigger current applied to the first n-type doped region 52 and turning on the parasitic PNPN thyristor will be decreased, and latch-up may occur in the internal circuit region R3 more easily. As shown in FIG. 8 and FIG. 4, in some embodiments, the length L illustrated in FIG. 8 (i.e. the distance DS1) may be about 28.8 μm, the trigger current applied to the first n-type doped region 52 and turning on the parasitic PNPN thyristor may be about −3.45 mA, and that is too low to prevent the latch-up in the internal circuit region R3.

To summarize the above descriptions, according to the semiconductor device in the present invention, the deep n-type well region may be expanded to be located under the second p-type well region and separated from the third n-type doped region for reducing electrons flowing into the third n-type doped region, increasing the trigger current, and suppressing the latch-up occurred in the internal circuit region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor substrate comprising:
a first portion located within a diode region;
a second portion located within a guard ring region; and
a third portion located within an internal circuit region;
a first p-type well region, wherein at least a part of the first p-type well region is disposed in the first portion;
a first n-type well region disposed in the second portion;
a second p-type well region, wherein a part of the first n-type well region is located between the first p-type well region and the second p-type well region in a horizontal direction;
a second n-type well region disposed in the third portion, wherein a part of the second p-type well region is located between the first n-type well region and the second n-type well region in the horizontal direction; and
a deep n-type well region disposed in the semiconductor substrate, wherein the deep n-type well region is partly located under the first p-type well region, partly located under the first n-type well region, and partly located under the second p-type well region, and the deep n-type well region is separated from the second n-type well region.

2. The semiconductor device according to claim 1, further comprising:
a first n-type doped region disposed in the first p-type well region and located within the diode region;
a first p-type doped region disposed in the first p-type well region and located within the diode region; and
a second n-type doped region disposed in the first n-type well region and located within the guard ring region, wherein at least a part of the first p-type doped region is located between the first n-type doped region and the second n-type doped region in the horizontal direction.

3. The semiconductor device according to claim 2, wherein the first n-type doped region and the first p-type doped region are a part of a diode structure.

4. The semiconductor device according to claim 2, wherein the second n-type doped region and the first n-type well region are at least a part of a guard ring structure.

5. The semiconductor device according to claim 2, wherein the deep n-type well region is partly located under the first n-type doped region, partly located under the first p-type doped region, and partly located under the second n-type doped region.

6. The semiconductor device according to claim 2, further comprising:
a third n-type doped region disposed in the second p-type well region, wherein a part of the second n-type doped region is located between the first p-type doped region and the third n-type doped region in the horizontal direction.

7. The semiconductor device according to claim 6, wherein the deep n-type well region is partly located under the third n-type doped region.

8. The semiconductor device according to claim 6, wherein the deep n-type well region comprises a first edge located under the second p-type well region, and the first n-typed well region comprises a second edge located adjacent to the second p-type well region.

9. The semiconductor device according to claim 8, wherein a distance between the first edge and a center point of the first n-type doped region in the horizontal direction is greater than a distance between the second edge and the center point of the first n-type doped region in the horizontal direction.

10. The semiconductor device according to claim 9, wherein the second n-type well region comprises a third edge located adjacent to the part of the second p-type well region located between the first n-type well region and the second n-type well region in the horizontal direction, and the distance between the first edge and the center point of the first n-type doped region in the horizontal direction is less than a distance between the third edge and the center point of the first n-type doped region in the horizontal direction.

11. The semiconductor device according to claim 9, wherein a length of the deep n-type well region in the horizontal direction is greater than the distance between the first edge and the center point of the first n-type doped region in the horizontal direction.

12. The semiconductor device according to claim 8, wherein the first edge is located under the third n-type doped region.

13. The semiconductor device according to claim 8, further comprising:
an isolation structure disposed in the semiconductor substrate, wherein a part of the isolation structure is located between the second n-type doped region and the third n-type doped region in the horizontal direction, and the first edge is located under the part of the isolation structure and the second p-type well region.

14. The semiconductor device according to claim 6, wherein the third n-type doped region is a source/drain region of an n-type transistor structure.

15. The semiconductor device according to claim 6, further comprising:
a second p-type doped region disposed in the second n-type well region and located within the internal circuit region, wherein the third n-type doped region is located between the second n-type doped region and the second p-type doped region in the horizontal direction.

16. The semiconductor device according to claim 15, further comprising:
an isolation structure disposed in the semiconductor substrate, wherein a part of the isolation structure is located between the third n-type doped region and the second p-type doped region in the horizontal direction, the deep n-type well region comprises a first edge located under the second p-type well region, and the first edge is further located under the part of the isolation structure.

17. The semiconductor device according to claim 15, wherein the second p-type doped region is a source/drain region of a p-type transistor structure.

18. The semiconductor device according to claim 15, wherein the second n-type doped region and the second p-type doped region are electrically connected to a first voltage terminal, and the first p-type doped region and the third n-type doped region are electrically connected to a second voltage terminal different from the first voltage terminal.

19. The semiconductor device according to claim 18, further comprising:
a fourth n-type doped region disposed in the second n-type well region and located within the internal circuit region, wherein the second p-type doped region is located between the third n-type doped region and the fourth n-type doped region in the horizontal direction, and the fourth n-type doped region is electrically connected to the first voltage terminal.

20. The semiconductor device according to claim 18, further comprising:
a third p-type doped region disposed in the second p-type well region, wherein the fourth n-type doped region is located between the second p-type doped region and the third p-type doped region in the horizontal direction, and the third p-type doped region is electrically connected to the second voltage terminal.
